(19) United States
(12) Patent Application Publication
(10) Pub. No.: US 2025/0218811 A1
(43) Pub. Date: Jul. 3, 2025

(54) SCRUBBER APPARATUS

(71) Applicant: Samsung Electronics Co., Ltd., Suwon-si (KR)

(72) Inventors: Keunsun Kim, Suwon-si (KR); Hyunwook Lee, Suwon-si (KR); Booseok Yang, Cheonan-si (KR); Raetaek Oh, Cheonan-si (KR)

(73) Assignees: Samsung Electronics Co., Ltd., Suwon-si (KR); SEMES CO., LTD., Cheonan-si (KR)

(21) Appl. No.: 18/889,022

(22) Filed: Sep. 18, 2024

(30) Foreign Application Priority Data
Dec. 28, 2023 (KR) 10-2023-0195664
Mar. 7, 2024 (KR) 10-2024-0032682

(51) Int. Cl. H01L 21/67

(52) U.S. Cl. CPC H01L 21/67046; H01L 21/67051; H01L 21/67253

(57) ABSTRACT

A scrubber apparatus includes a chamber, an air intake unit connected to a semiconductor processing apparatus including a plurality of processing chambers and intaking exhaust gas discharged from the plurality of processing chambers into a processing space inside the chamber, a treated water supply pipe installed in the processing space, connected to a plurality of spray nozzles spraying treated water, and supplying the treated water to the processing space, a wastewater discharge unit discharging wastewater in which the exhaust gas is dissolved by the treated water from the processing space, a gas discharge unit connected to the chamber and discharging residual gas, and a controller communicatively connected to the semiconductor processing apparatus and adjusting an amount of the treated water supplied to the processing space based on the number of active processing chambers in progress among the plurality of processing chambers.

### CROSS-REFERENCE TO RELATED APPLICATION(S)

This application claims the benefit under 35 USC 119(a) of Korean Patent Application No. 10-2023-0195664 filed on Dec. 28, 2023 and Korean Patent Application No. 10-2024-0032682 filed on Mar. 7, 2024 in the Korean Intellectual Property Office, the entire disclosures of which are incorporated herein by reference for all purposes.

### BACKGROUND

Aspects of the present inventive concept relate to a scrubber apparatus for reducing pollutants.

In production lines that produce semiconductor devices by performing various semiconductor processes on wafers and the like, various contaminants may be generated as by-products. The production line may additionally include various devices to remove or reduce contaminants generated during the semiconductor production process. For example, a production line may include scrubber equipment to reduce exhaust gases containing pollutants, and scrubber equipment may reduce pollutants emitted from production lines by dissolving exhaust gases in treated water. However, it is necessary to continuously supply treated water to operate the scrubber apparatus, and problems with excessive use of treated water may occur in this process.

### SUMMARY

Example embodiments provide a scrubber apparatus in which an amount of treated water used may be reduced without reducing a treatment efficiency of pollutants by monitoring the status of semiconductor processing apparatuses discharging exhaust gas to a scrubber apparatus and controlling the amount of treated water used by the scrubber apparatus.

According to example embodiments, a scrubber apparatus includes a chamber, an air intake unit connected to a semiconductor processing apparatus including a plurality of processing chambers and intaking exhaust gas discharged from the plurality of processing chambers into a processing space inside the chamber, a treated water supply pipe installed in the processing space, connected to a plurality of spray nozzles spraying treated water, and configured to supply the treated water to the processing space, a wastewater discharge unit configured to discharge wastewater in which the exhaust gas is dissolved by the treated water, from the processing space, a gas discharge unit connected to the chamber and configured to discharge residual gas, and a controller communicatively connected to the semiconductor processing apparatus and configured to adjust an amount of the treated water supplied to the processing space based on the number of active processing chambers in progress among the plurality of processing chambers.

According to example embodiments, a scrubber apparatus includes a first scrubber stage including an air intake unit intaking exhaust gas discharged from a plurality of processing chambers, a plurality of first spray nozzles spraying treated water into the exhaust gas drawn by the air intake unit, and a first chamber connected to the air intake unit and providing a first processing space in which the exhaust gas is dissolved in the treated water sprayed from the plurality of first spray nozzles, a second scrubber stage including a plurality of second spray nozzles spraying the treated water onto the exhaust gas having passed through the first scrubber stage, a second chamber separated from the first processing space and providing a second processing space in which the exhaust gas is dissolved in the treated water sprayed from the plurality of second spray nozzles, and a gas discharge unit discharging residual gas having passed through the second processing space, and a controller configured to adjust an amount of the treated water supplied to each of the first processing space and the second processing space based on the number of active processing chambers in progress among the plurality of processing chambers.

According to example embodiments, a scrubber apparatus includes a chamber, an air intake unit connected to a plurality of processing chambers and intaking exhaust gas discharged from the plurality of processing chambers into a processing space inside the chamber, a treated water supply pipe installed in the processing space, connected to a plurality of spray nozzles spraying treated water, and supplying the treated water to the processing space, a wastewater discharge unit configured to discharge wastewater in which the exhaust gas is dissolved by the treated water from the processing space, and a gas discharge unit connected to the chamber and discharging residual gas. The treated water supply pipe receives the treated water discharged after circulation in at least one of the plurality of processing chambers.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a production line in which a semiconductor processing is performed according to example embodiments;

FIG. 2 is a diagram illustrating a processing chamber included in a semiconductor processing apparatus according to example embodiments;

FIGS. 3 and 4 are drawings illustrating a scrubber apparatus according to example embodiments;

FIG. 5 is a diagram illustrating the operation of a scrubber apparatus according to example embodiments;

FIGS. 6 and 7 are diagrams illustrating the operation of a scrubber apparatus according to example embodiments;

FIGS. 8 and 9 are diagrams illustrating the operation of a scrubber apparatus in a first operating condition;

FIGS. 10 and 11 are diagrams illustrating the operation of a scrubber apparatus in a second operating condition;

FIGS. 12 and 13 are diagrams illustrating the operation of a scrubber apparatus in a third operating condition; and

FIG. 14 is a diagram illustrating a scrubber apparatus according to example embodiments.

### DETAILED DESCRIPTION

Hereinafter, example embodiments will be described with reference to the accompanying drawings.

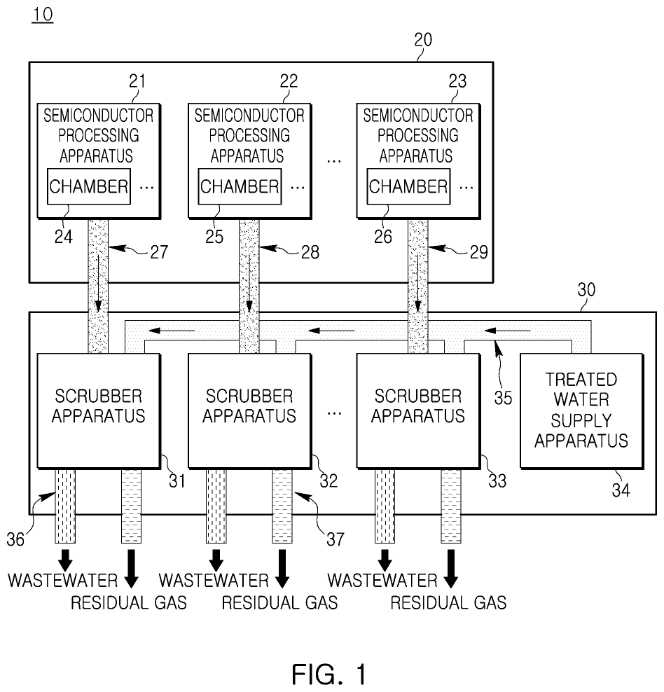

FIG. 1 is a diagram illustrating a production line in which semiconductor processing is performed according to example embodiments.

Referring to FIG. 1, a production line 10 according to example embodiments may include a main area 20 in which semiconductor processing apparatuses 21, 22, and 23 (i.e., 21 to 23) are disposed and semiconductor processing is performed, a plenum area 30 spatially separated from the main area 20, and the like. In the plenum area 30, apparatuses for maintaining and managing the main area 20 and apparatuses for processing by-products produced as the semiconductor processing progresses in the semiconductor processing apparatuses 21 to 23 may be placed. Each of the semiconductor processing apparatuses 21 to 23 may include a plurality of chambers 24, 25, and 26 (i.e., 24 to 26). In example embodiments, the number of chambers 24 to 26 included in each of the semiconductor processing apparatuses 21 to 23 may be eight.

In an example embodiment illustrated in FIG. 1, a plurality of scrubber apparatuses 31, 32, and 33 (i.e., 31 to 33), a treated water supply apparatus 34, and the like may be disposed in the plenum area 30. The scrubber apparatuses 31 to 33 are equipment that treats exhaust gas generated during a semiconductor process, and for example, may dissolve exhaust gas containing pollutants in treated water and reduce the exhaust gas. The treated water supply apparatus 34 supplies the treated water necessary for the scrubber apparatuses 31 to 33 to reduce exhaust gas. For example, the treated water may be de-ionized water.

The chambers 24 to 26 respectively included in the semiconductor processing apparatuses 21 to 23 may be equipment that performs at least one of semiconductor processes such as a photo process, a deposition process, an etching process, a cleaning process, and the like. Along with the semiconductor processing apparatuses 21 to 23, the main area 20 may include an Overhead Hoist Transfer (OHT) system that transfers a Front Open Unified Pod (FOUP), which is a container containing a plurality of wafers. Each of the chambers 24 to 26 may perform semiconductor processes on wafers placed in a FOUP by the OHT system and transferred to each of the semiconductor processing apparatuses 21 to 23.

For example, a cleaning process to remove residues or contaminants present on the wafer may be performed in at least one of the semiconductor processing apparatuses 21 to 23. Generally, the cleaning process may include cleaning the wafer using an organic solvent, cleaning the wafer using deionized water, and drying the wafer.

In a cleaning process using an organic solvent, exhaust gas containing contaminants such as volatile organic compounds (VOCs) may be generated as a by-product. For such exhaust gases, emission regulations are applied for the total hydrocarbons (THC) contained in the exhaust gases, so it is essential to reduce pollutants before emitting exhaust gases.

Referring to FIG. 1, exhaust gas generated as a by-product in the semiconductor processing apparatuses 21 to 23 may be delivered to the scrubber apparatuses 31 to 33 through gas pipes 27, 28, and 29 (i.e., 27 to 29). Gas pipes 27 to 29 provide a delivery path for exhaust gases between the main area 20 and the plenum area 30, and at least one pump, valve, and the like for controlling the movement of exhaust gas may be coupled to the gas pipes 27 to 29. An air intake unit may comprise the gas pipes 27 to 29, the at least one pump, the valve, and the like.

Each of the scrubber apparatuses 31 to 33 may perform a treatment operation to reduce exhaust gas. The scrubber apparatuses 31 to 33 according to an example embodiment illustrated in FIG. 1 may reduce exhaust gas in a wet manner using treated water supplied from the treated water supply apparatus 34 through the treated water supply pipe 35. For example, the scrubber apparatuses 31 to 33 include a plurality of spray nozzles that spray treated water, and may dissolve contaminants in the exhaust gas with the treated water sprayed by the plurality of spray nozzles. Treated water with dissolved contaminants may be discharged in the form of wastewater through a wastewater discharge unit comprising, for example, the wastewater pipe 36. The residual gas remaining after dissolving the exhaust gas with treated water may be discharged to the outside through a gas discharge unit comprising, for example, residual gas pipe 37.

In order for the scrubber apparatuses 31 to 33 to perform the treatment task of reducing exhaust gases, supply of treated water is required, and the treated water supply apparatus 34 may supply the same amount of treated water to the scrubber apparatuses 31 to 33 regardless of whether the semiconductor processing apparatuses 21 to 23 that export exhaust gas to the scrubber apparatuses 31 to 33 are in operation. In addition, each of the scrubber apparatuses 31 to 33 may open a plurality of spray nozzles so that the same amount of treated water is sprayed regardless of the number of chambers 24 to 26 in operation in each of the semiconductor processing apparatuses 21 to 23. Accordingly, excessive waste of treated water may occur in the scrubber apparatuses 31 to 33 for reducing exhaust gas.

In example embodiments, each of the scrubber apparatuses 31 to 33 may receive feedback from the results of monitoring the status of the chambers 24 to 26 in which the process is performed in each of the semiconductor processing apparatuses 21 to 23, and may adjust the amount of treated water consumed in treatment operations that reduce emissions. For example, based on the results of monitoring the status of the chambers 24 to 26 included in each of the semiconductor processing apparatuses 21 to 23, each of the scrubber apparatuses 31 to 33 may dynamically adjust the amount of treated water sprayed from the plurality of spray nozzles. Alternatively, based on the results of monitoring the status of the chambers 24 to 26 included in each of the semiconductor processing apparatuses 21 to 23, the treated water supply apparatus 32 may dynamically adjust the amount of treated water supplied to each of the scrubber apparatuses 31 to 33. By adjusting the amount of treated water consumed by each of the scrubber apparatuses 31 to 33 according to the number of active processing chambers that actually perform a semiconductor processing emitting exhaust gas among the chambers 24 to 26, the amount of treated water used may be reduced while maintaining the effect of reducing pollutants at a similar level as before.

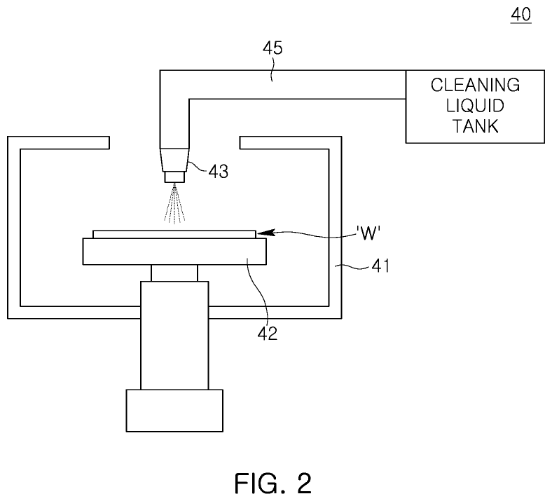

FIG. 2 is a diagram simply illustrating a processing chamber included in a semiconductor processing apparatus according to example embodiments.

The processing chamber 40 according to an example embodiment illustrated in FIG. 2 may be a processing chamber in which a cleaning process for the wafer W is performed using an organic solvent. Referring to FIG. 2, the processing chamber 40 may include a housing 41, an electrostatic chuck 42, a cleaning nozzle 43, a cleaning liquid tank 44, and a cleaning liquid pipe 45.

The wafer W is seated on the electrostatic chuck 42, and the electrostatic chuck 42 may rotate while the wafer W is seated. In example embodiments, the wafer W may be rotated by the electrostatic chuck 42 at a speed of 10 rpm to 6000 rpm. The housing 41 prevents the cleaning solution applied to the wafer W from leaking out, and a pipe that may discharge the cleaning solution used to clean the wafer W may be installed on one side of the housing 41.

The cleaning nozzle 43 that sprays the cleaning solution is installed above the electrostatic chuck 42 and may discharge the cleaning solution to the wafer W. For example, the cleaning solution may include an organic solvent diluted in deionized water. When the cleaning solution is sprayed by the cleaning nozzle 43 at a position close to the center of the electrostatic chuck 42, the cleaning solution may be evenly applied to the entire surface of the wafer W as the wafer W is rotated by the electrostatic chuck 42. In example embodiments, the organic solvent may include isopropyl alcohol.

As described above, in the cleaning process of cleaning the wafer W using an organic solvent, exhaust gas containing contaminants such as volatile organic compounds is generated, and it is necessary to reduce pollutants before emitting such exhaust gases. The exhaust gas generated in the processing chamber 40 is moved to a separate scrubber apparatus for treatment before discharge, and a scrubber apparatus may reduce pollutants contained in exhaust gas by using treated water to dissolve pollutants contained in the exhaust gas.

The scrubber apparatus may include a spray nozzle that sprays treated water into the movement path of the exhaust gas flowing in from the processing chamber 40. If a certain amount of treated water is continuously sprayed from the spray nozzle regardless of the amount of exhaust gas flowing into the scrubber apparatus, the amount of unnecessarily consumed treated water may increase. Accordingly, in example embodiments, the scrubber apparatus may adjust the amount of treated water sprayed from the spray nozzle based on the state of the semiconductor processing apparatus 40. To control the amount of treated water sprayed from the spray nozzle, the scrubber apparatus may receive feedback on the status of the processing chamber 40 through a communication interface such as TCP/IP. Therefore, the amount of treated water consumed by a scrubber apparatus may be reduced.

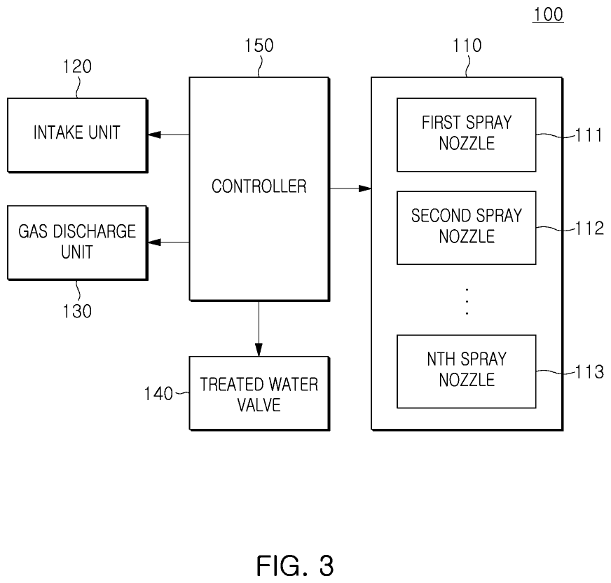

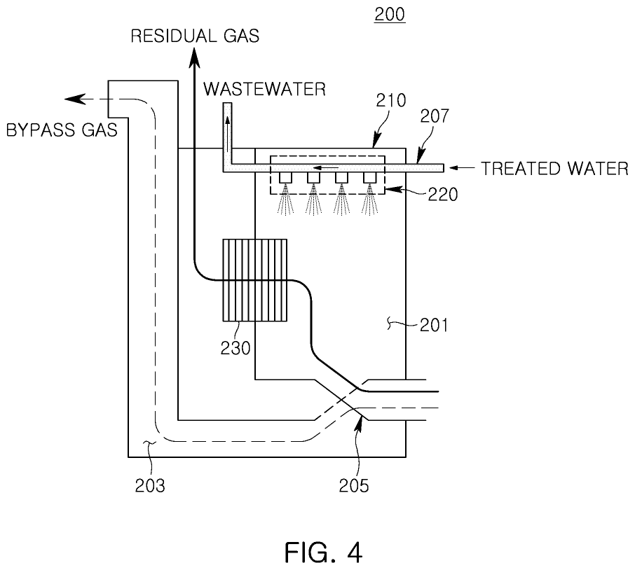

FIGS. 3 and 4 are drawings illustrating a scrubber apparatus according to example embodiments.

Referring to FIG. 3, a scrubber apparatus 100 according to example embodiments may include a plurality of spray nozzles 110, an air intake unit 120, a gas discharge unit 130, a treated water valve 140, and a controller 150. In addition to the components illustrated in FIG. 3, the scrubber apparatus 100 may further include a treated water supply pipe that supplies treated water to the plurality of spray nozzles 110, a gas pipe that provides a movement path for exhaust gas containing pollutants to be reduced, and the like.

The plurality of spray nozzles 110 include first to Nth spray nozzles 111 to 113, and may spray treated water into exhaust gas containing contaminants. The ejection amount of treated water for each of the first to Nth spray nozzles 111 to 113 may be adjusted by the controller 150.

The air intake unit 120 may suck exhaust gas from a plurality of processing chambers included in a semiconductor processing apparatus. The gas discharge unit 130 may discharge residual gas in which pollutants have been reduced by the treated water sprayed from the plurality of spray nozzles 110 to the outside. For example, the air intake unit 120 and the gas discharge unit 130 each include at least one pump for moving gas in a specific direction, and the gas discharge unit 130 may include a filter to further remove contaminants contained in the residual gas. For example, the filter included in the gas discharge unit 130 may be a demister filter.

The treated water valve 140 is installed in a pipe (e.g., a treated water supply pipe) that supplies treated water to the plurality of spray nozzles 110 and may control the amount of treated water moving to the plurality of spray nozzles 110. Depending on example embodiments, the controller 150 may control the plurality of spray nozzles 110 and/or the treated water valve 140 to adjust the amount of treated water sprayed into the exhaust gas containing pollutants.

The controller 150 may adjust the amount of treated water sprayed into the exhaust gas based on the operating status of the processing chambers that discharge exhaust gas to the scrubber apparatus 100. For example, the controller 150 is connected to a semiconductor processing apparatus including processing chambers, to communicate therewith, through a TCP/IP interface or the like, and may receive feedback on whether a semiconductor processing is actually running in the processing chambers, the number of processing chambers in which the semiconductor processing is running, and the like.

In example embodiments, the controller 150 may determine the number of active processing chambers in which a semiconductor processing is actually being executed among the processing chambers, and adjust the amount of treated water sprayed from the plurality of spray nozzles 110 according to the number of active processing chambers. As described above, the controller 150 may adjust the ejection amount of treated water from each of the plurality of spray nozzles 110 and/or the amount of treated water supplied through the treated water supply pipe to the plurality of spray nozzles 110, thereby adjusting the amount of treated water sprayed into the exhaust gas.

For example, the controller 150 may control the treated water ejection amount of each of the plurality of spray nozzles 110 differently depending on the number of active processing chambers. When the number of active processing chambers is greater than the first reference number, the controller 150 may set the treated water ejection amount of each of the plurality of spray nozzles 110 as the reference ejection amount. For example, the reference ejection amount may be the maximum treated water ejection amount of each of the plurality of spray nozzles 110.

When the number of active processing chambers is the first reference number or less, the controller 150 may set the treated water ejection amount of each of the plurality of spray nozzles 110 to be smaller than the reference ejection amount. For example, the controller 150 may set the treated water ejection amount of each of the plurality of spray nozzles 110 to 50% of the reference ejection amount under the condition that the number of active processing chambers is less than or equal to the first reference number.

In example embodiments, the controller 150 may adjust the amount of treated water ejected into the exhaust gas based on the ratio of the number of active processing chambers to the total number of semiconductor processing apparatuses. Depending on example embodiments, the controller 150 may further finely adjust the treated water ejection amount of each of the plurality of spray nozzles 110 based on the number of active processing chambers. Additionally, separately from directly controlling the ejection amount of treated water for each of the plurality of spray nozzles 110, the controller 150 may also control, via the treated water valve 140, the amount of treated water flowing through the treated water supply pipe to which the plurality of spray nozzles 110 are connected.

Referring to FIG. 4, a scrubber apparatus 200 according to example embodiments may include a chamber 210, a plurality of spray nozzles 220, a filter 230, and the like. A treated water supply pipe 207 through which treated water flows is installed inside the chamber 210, and a plurality of spray nozzles 220 may be connected to the treated water supply pipe 207. Scrubber apparatus 200 is an example embodiment of the scrubber apparatus 100 illustrated in FIG. 3.

The plurality of spray nozzles 220 (comprising, e.g., first to Nth spray nozzles 111 to 113) may spray treated water into the exhaust gas flowing into the processing space 201 of the chamber 210. As previously described with reference to FIG. 3, the ejection amount of treated water from each of the plurality of spray nozzles 220 may be adjusted by a controller (e.g., controller 150). At least some of the contaminants contained in the exhaust gas flowing into the processing space 201 may be dissolved by the treated water sprayed from the plurality of spray nozzles 220, thereby reducing the contaminants in the exhaust gas. As previously discussed, the exhaust gas, which is emitted by a semiconductor processing apparatus, may include contaminants, such as volatile organic compounds.

Referring to FIG. 4, a plurality of spray nozzles 220 spray treated water toward the processing space 201, and the treated water may be deionized water. The remaining treated water that is not sprayed through the plurality of spray nozzles 220 may be discharged to the outside as wastewater by a wastewater discharge unit, or may be recovered by the scrubber apparatus 200 and supplied back to the treated water supply pipe 207. In an example embodiment illustrated in FIG. 4, four spray nozzles 220 are illustrated as being mounted on the treated water supply pipe 207, but this is only one embodiment, and the number of spray nozzles 220 may be changed variously.

The treated water supply pipe 207 may be connected to the treated water supply apparatus to receive treated water. For example, the treated water supply apparatus may supply treated water stored in a separate treated water tank to the treated water supply pipe 207. Additionally, in example embodiments, the treated water supply apparatus may recycle treated water discharged from a semiconductor processing apparatus that discharges exhaust gas to the scrubber apparatus 200 and supply the treated water to the treated water supply pipe 207.

As previously described with reference to FIG. 2, the cleaning equipment may perform a cleaning process on the wafer using a cleaning solution mixed with an organic solvent and treated water. In example embodiments, unused treated water may be generated in the process of diluting the organic solvent with treated water, and treated water that is not used and drained from a semiconductor processing apparatus may be supplied to the scrubber apparatus 200 and reused.

Exhaust gases emitted from processing chambers included in a semiconductor processing apparatus may flow into the processing space 201 where pollutant reduction treatment using treated water is performed through the air intake unit 120 where a plate 205 (e.g., a bypass flap, a diverter, etc.) is installed. When pollutants are reduced by the treated water sprayed into the processing space 201, the exhaust gas may pass through the filter 230. At least some of the remaining contaminants that are not removed by the treated water are removed by the filter 230, and the residual gas may be discharged to the outside through the gas discharge unit 130.

For example, at least one fan may be disposed at the rear of the filter 230 so that the residual gas that has passed through the processing space 201 and the filter 230 from the intake portion is discharged to the outside of the scrubber apparatus 200. For example, depending on the operating status of the processing chambers connected to the scrubber apparatus 200, the gas flowing into the air intake unit may be discharged as bypass gas through the bypass flow path 203 rather than the processing space 201. Controller 150 may control the plate 205 such that the plate may move between a first position and a second position. In the first position, the plate 205 may divert gas flowing in the air intake unit toward the processing space 201. In the second position, the plate 205 may divert gas flowing in the air intake unit toward the bypass flow path 203

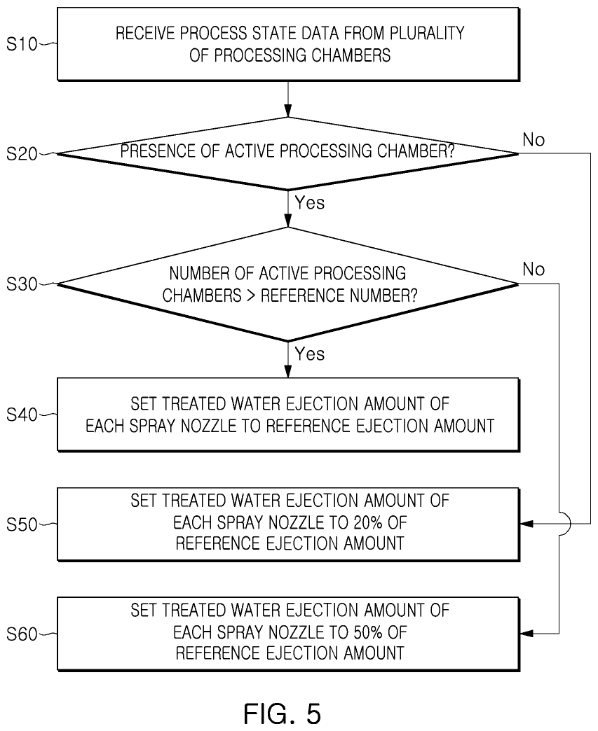

FIG. 5 is a diagram illustrating the operation of a scrubber apparatus according to example embodiments.

Referring to FIG. 5, the operation of the scrubber apparatus according to example embodiments may begin with the controller of the scrubber apparatus receiving process state data from a plurality of processing chambers (S10). The scrubber apparatus is connected to communicate with a semiconductor processing apparatus including a plurality of processing chambers through a predetermined interface, and may receive process status data to monitor the operating status of the plurality of processing chambers. The controller of the scrubber apparatus may determine whether there is an active processing chamber in which a semiconductor processing is actually in progress based on the process status data (S20).

As a result of the determination in operation S20, when there is no active processing chamber, the controller of the scrubber apparatus may set the treated water ejection amount of each spray nozzle to 20% of the reference ejection amount (S50). The reference ejection amount may be the maximum treated water ejection amount of each spray nozzle. However, the figure of 20% of the reference ejection amount is only an example, and depending on example embodiments, under conditions where an active processing chamber does not exist, the ejection amounts of treated water for respective spray nozzles may be set to 5%, 10%, 15%, 25%, and the like of the reference ejection amount.

On the other hand, when there is an active processing chamber as a result of the determination in operation S20, the scrubber apparatus may compare the number of active processing chambers with the reference number based on the process state data (S30). As a result of the comparison in operation S30, when the number of active processing chambers is greater than the reference number, the controller of the scrubber apparatus may set the treated water ejection amount of each spray nozzle to the maximum reference ejection amount (S40).

As a result of the comparison in operation S30, when the number of active processing chambers is a reference number or less, the controller of the scrubber apparatus may set the treated water ejection amount of each spray nozzle to 50% of the ejection injection amount (S60). However, the figure of 50% of the reference ejection amount is also just an example, and depending on example embodiments, under the condition that active processing chambers exist and the number thereof is the reference number or less, the treated water ejection amounts of respective spray nozzles may be set to 40%, 45%, 50%, 55%, 60%, 70%, and the like of the reference ejection amount.

In an example embodiment described with reference to FIG. 5, the controller of the scrubber apparatus may adjust the ejection amount of treated water from each spray nozzle according to the number of active processing chambers. For example, if there are no active processing chambers, the treated water ejection amount of each spray nozzle is set to a predetermined minimum value, and if the number of active processing chambers is greater than the reference number, the treated water ejection amount of each spray nozzle may be set to the maximum reference ejection amount. On the other hand, when there are active processing chambers and the number thereof is the reference number or less, the controller of the scrubber apparatus may set the treated water ejection amount of each spray nozzle to an intermediate value between a minimum value and a maximum value.

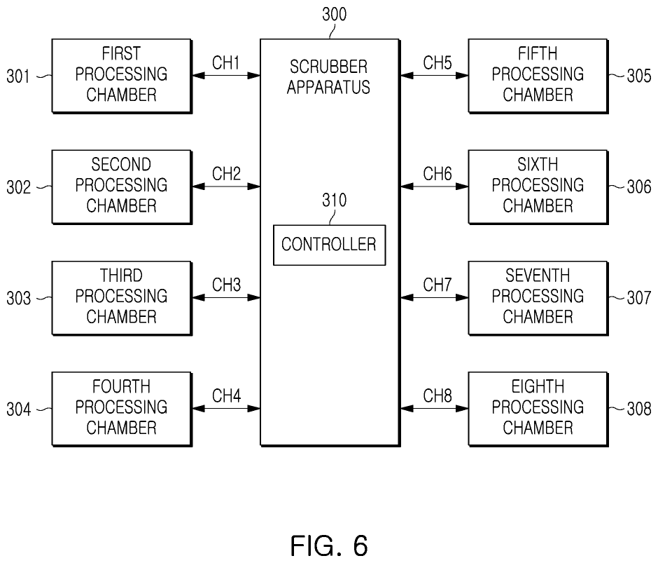

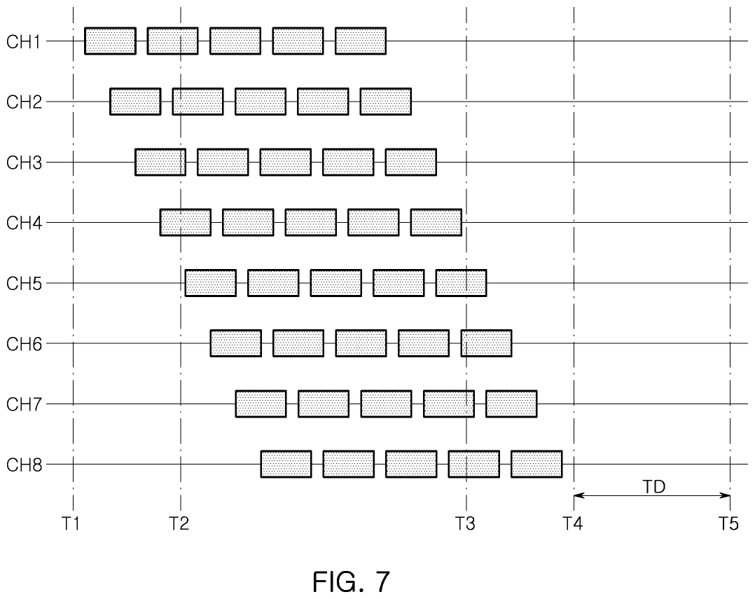

FIGS. 6 and 7 are drawings illustrating the operation of the scrubber apparatus according to example embodiments.

Referring to FIG. 6, the controller 310 of the scrubber apparatus 300 according to example embodiments may be connected to communicate with a plurality of processing chambers 301 to 308 (similar to the previously discussed chambers 24 to 26). For example, a plurality of processing chambers 301 to 308 are included in one semiconductor processing equipment, and the semiconductor processing equipment and the scrubber apparatus 300 may be connected to enable communication.

The controller 150 may dynamically control the amount of treated water consumed by the scrubber apparatus 300 based on the operating states of the plurality of processing chambers 301 to 308. Accordingly, the consumption of treated water of the scrubber apparatus 300 may be reduced without reducing the effect of reducing pollutants contained in the exhaust gas discharged from the plurality of processing chambers 301 to 308.

For example, the controller 310 of the scrubber apparatus 300 may be connected to a plurality of processing chambers 301 to 308 through a plurality of communication channels CH1 to CH8. The controller 310 may identify an active processing chamber in which a semiconductor processing emitting exhaust gas is being performed among the plurality of processing chambers 301 to 308 through each of the communication channels CH1 to CH8. The controller 310 controls the treated water sprayed in the processing space of the scrubber apparatus 300 based on the number of active processing chambers and/or the ratio of active processing chambers among the plurality of processing chambers 301 to 308. The amount may be adjusted. Hereinafter, the operation of the scrubber apparatus 300 will be described in more detail with reference to FIG. 7.

Referring to FIG. 7, before the first time point T1, there may not be an active processing chamber among the plurality of processing chambers 301 to 308. Therefore, during the time before the first time point T1, the controller 310 may control the spray nozzles included in the scrubber apparatus 300 so that the minimum amount of treated water is sprayed into the processing space of the scrubber apparatus 300. For example, the controller 310 may maintain the amount of treated water sprayed from the spray nozzles of the scrubber apparatus 300 at a level of 20% of the maximum ejection amount during the time before the first time point T1. Depending on example embodiments, the controller 310 may control the scrubber apparatus 300 so that treated water is not sprayed into the processing space of the scrubber apparatus 300 before the first time point T1.

Referring to FIG. 7, during the time between the first time point T1 and the second time point T2, a semiconductor processing may be started in the first to fourth semiconductor processing apparatuses 301 to 304 connected to the first to fourth communication channels CH1 to CH4. The controller 310 may increase the amount of treated water sprayed into the processing space of the scrubber apparatus 300, from a first time point T1 at which a semiconductor processing is monitored as being executed in at least one of the processing chambers 301 to 308. For example, during the time between the first time point T1 and the second time point T2 when the number of active processing chambers performing a semiconductor processing is 4 or less, the controller 310 may maintain the amount of treated water sprayed from the spray nozzles of the scrubber apparatus 300 at a level of 50% of the maximum ejection amount.

For example, from the second time point T2, the semiconductor processing may also start in the fifth semiconductor processing apparatus 305 connected to the scrubber apparatus 300 through the fifth channel CH5. Accordingly, as illustrated in FIG. 7, during the time between the second time point T2 and the third time point T3, the number of active processing chambers may be more than four. The controller 310 of the scrubber apparatus 300 may maintain the amount of treated water sprayed from the spray nozzles of the scrubber apparatus 300 at the maximum ejection amount under the condition that the number of active processing chambers is more than four.

Referring to FIG. 7, from the third time point T3, the number of active processing chambers may decrease again to 4 or less. Thus, during the time between the third time point T3 and the fourth time point T4, the controller 310 of the scrubber apparatus 300 may reduce the amount of treated water sprayed from the spray nozzles of the scrubber apparatus 300 to about 50% of the maximum ejection amount.

As such, in example embodiments, the amount of treated water sprayed from the spray nozzles may be adjusted by referring to the number of active processing chambers that actually perform the semiconductor processing among the processing chambers 301 to 308. Accordingly, the amount of treated water used by the scrubber apparatus 300 may be reduced while maintaining the performance of reducing pollutants contained in the exhaust gas discharged from the processing chambers 301 to 308 without significant change.

In an example embodiment illustrated in FIG. 7, despite the fact that there is no active processing chamber performing a semiconductor processing after the fourth time point T4, the amount of treated water sprayed into the processing space of the scrubber apparatus 300 may be maintained at a certain level. Referring to FIG. 7, the ejection amount of treated water from the spray nozzles may be maintained at a level of 50% of the maximum ejection amount from the fourth time T4 to the fifth time T5 when a predetermined delay time TD has elapsed. This may be to ensure time to sufficiently remove pollutants contained in the exhaust gas flowing in from the processing chambers 301 to 308 during the time before the fourth time point T4.

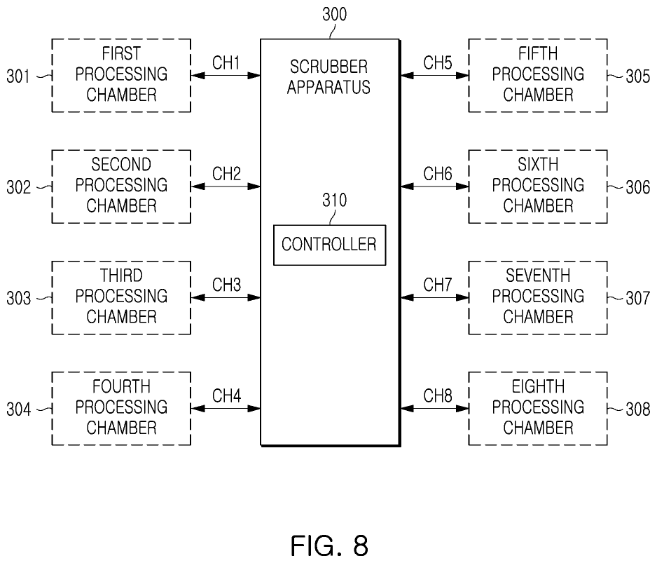

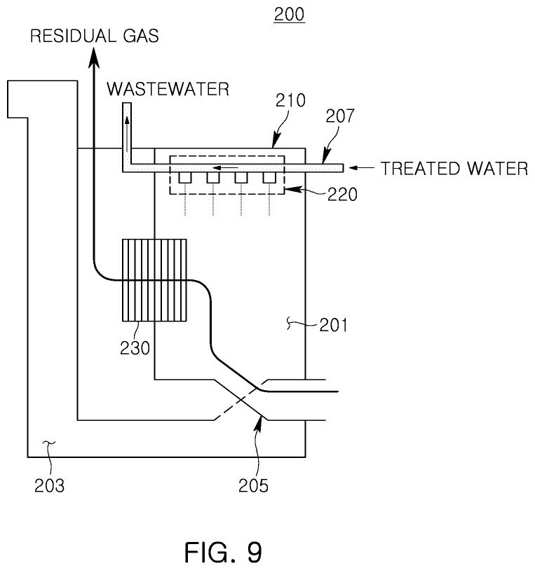

FIGS. 8 and 9 are diagrams illustrating the operation of the scrubber apparatus in the first operating condition.

Referring to FIG. 8, the first operating condition may be an operating condition in which there is no active processing chamber that actually performs a semiconductor processing among the plurality of processing chambers 301 to 308. Therefore, the controller 3103 of the scrubber apparatus 300 may set the treated water ejection amount of each of the spray nozzles that spray treated water to the minimum to remove contaminants contained in the exhaust gas discharged from the active processing chamber.

Referring to FIG. 9, the scrubber apparatus 200 includes a processing space 201 connected to an intake portion where the plate 205 is installed and receiving exhaust gas, and a plurality of spray nozzles 220 may be installed in the processing space 201. The plurality of spray nozzles 220 are connected to the treated water supply pipe 207, and the ejection amount of treated water for each of the plurality of spray nozzles 220 may be controlled by the controller.

Since there is no active processing chamber in the first operating condition, the controller may adjust the treated water ejection amount of each of the plurality of spray nozzles 220 to the minimum. For example, as the ejection amount of treated water is adjusted to the minimum, almost no treated water may be sprayed from each of the plurality of spray nozzles 220. In example embodiments, the controller may not limit the ejection amount of treated water of each of the plurality of spray nozzles 220 to 0 even under the first operating condition, such that the active processing chamber may quickly increase the treated water ejection amount of each of the plurality of spray nozzles 220 in response to the generated conditions.

In an example embodiment illustrated in FIG. 9, the treated water ejection amount of each of the plurality of spray nozzles 220 may be controlled together. However, depending on example embodiments, the controller may control the treated water ejection amount of at least some of the plurality of spray nozzles 220 differently. For example, in the first operating condition, the controller sets the treated water ejection amount of some of the plurality of spray nozzles 220 to the maximum ejection amount and sets the treated water ejection amount of the remaining spray nozzles 220 to 0. The total amount of treated water sprayed into the processing space 201 may be reduced. In this manner, the controller may control the amount of treated water sprayed into the processing space 201 by controlling the ejection amount of each of the plurality of spray nozzles 220.

However, depending on example embodiments, the controller may adjust the amount of treated water supplied to the treated water supply pipe 207 to which the plurality of spray nozzles 220 are connected. At least one valve (e.g., treated water valve 140) may be connected to the treated water supply pipe 207, and the controller may control the amount of treated water flowing along the treated water supply pipe 207 by adjusting the opening/closing operation and opening/closing degree of the valve. In this manner, the amount of treated water flowing into the treated water supply pipe 207 is adjusted while maintaining the ejection amount of each of the plurality of spray nozzles 220. In the first operating condition, the ejection amount of treated water into the processing space 201 may be set.

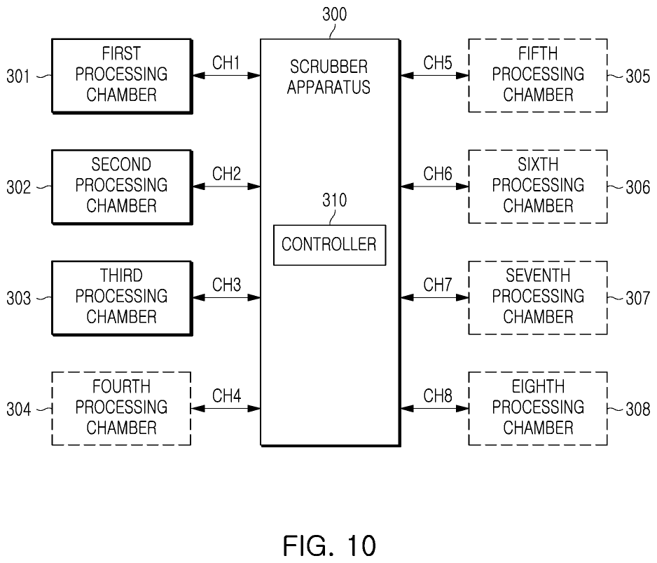

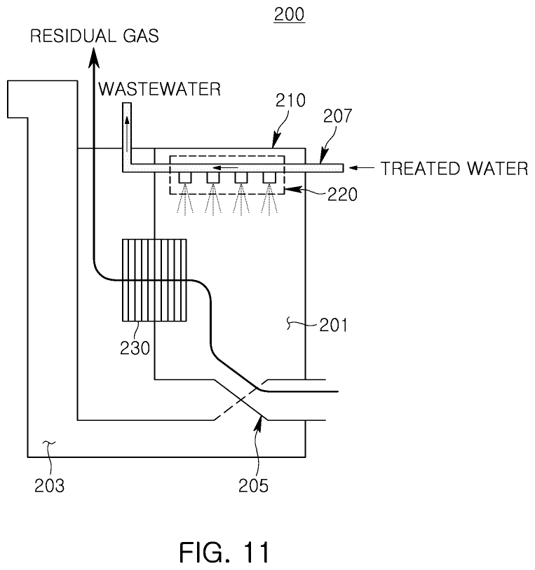

FIGS. 10 and 11 are diagrams illustrating the operation of the scrubber apparatus in the second operating condition.

Referring to FIG. 10, the second operating condition may be an operating condition in which an active processing chamber 301 to 303 that actually performs a semiconductor processing exists among the plurality of processing chambers 301 to 308. Therefore, the controller 310 of the scrubber apparatus 300 may set the treated water to be sprayed more than the minimum ejection amount from each of the spray nozzles that spray the treated water in order to remove contaminants contained in the exhaust gases emitted by the active processing chamber.

In an example embodiment illustrated in FIG. 10, the number of active processing chambers 301 to 303 may be three. The second operating condition may be an operating condition in which the number of active processing chambers 301 to 303 is less than or equal to the first reference number and is greater than the second reference number. For example, in the example embodiment described with reference to FIGS. 10 and 11, the first reference number may be 4 and the second reference number may be 0.

Referring to FIG. 11, a treated water supply pipe 207 and spray nozzles 220 may be installed in the scrubber apparatus 200 so that treated water may be sprayed into the processing space 201 of the chamber 210. In the second operating condition as described with reference to FIG. 10, the controller may set the ejection amount of treated water by the spray nozzles 220 to 50% of the maximum ejection amount. Therefore, as illustrated in FIGS. 9 and 11, the amount of treated water sprayed from the spray nozzles 220 may increase in the second operating condition compared to the first operating condition.

For example, the controller may increase the amount of treated water sprayed into the processing space 201 by increasing the individual ejection amount of each of the spray nozzles 220. Additionally, in another embodiment, the controller may increase the amount of treated water sprayed into the processing space 201 by increasing the number of spray nozzles 220 that spray treated water. Assuming the above embodiment, the controller may control the spray nozzles 220 so that treated water is sprayed from only one of the spray nozzles 220 in the first operating condition, and control the spray nozzles 220 so that treated water is sprayed from two of the spray nozzles 220 in the second operating condition.

Depending on example embodiments, the controller may adjust the amount of treated water supplied to the treated water supply pipe 207 to which the plurality of spray nozzles 220 are connected. At least one valve (e.g., treated water valve 140) may be connected to the treated water supply pipe 207, and the controller may control the amount of treated water flowing along the treated water supply pipe 207 by adjusting the opening/closing operation and opening/closing degree of the valve. In this manner, the amount of treated water flowing into the treated water supply pipe 207 is adjusted while maintaining the ejection amount of each of the plurality of spray nozzles 220. In the second operating condition, the ejection amount of treated water into the processing space 201 may be maintained.

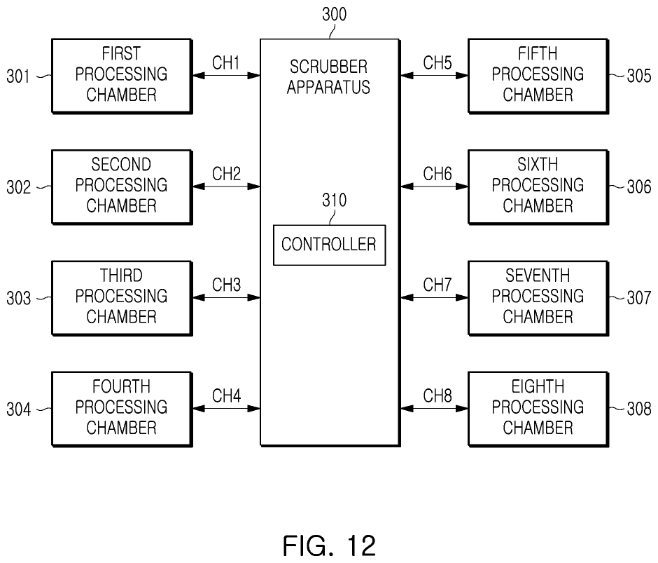

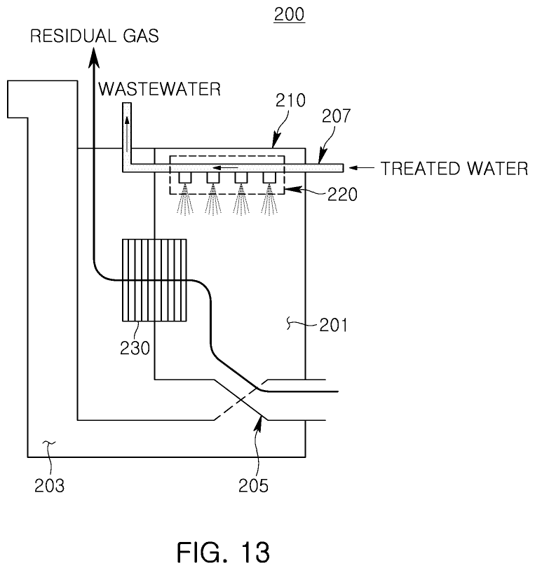

FIGS. 12 and 13 are diagrams illustrating the operation of the scrubber apparatus in the third operating condition.

Referring to FIG. 12, the third operating condition may be an operating condition in which the number of active processing chambers 301 to 308 that actually perform semiconductor processing among the plurality of processing chambers 301 to 308 is greater than the first reference number. As previously explained with reference to FIG. 10, assuming the first reference number is 4, as illustrated in FIG. 12, while the semiconductor processing is in progress in all processing chambers 301 to 308, the controller 310 of the scrubber apparatus 300 may determine that the third operating condition is satisfied.

Referring to FIG. 13, in the third operating condition, the treated water ejection amount of the spray nozzles 220 may be set to the reference ejection amount, which is the maximum ejection amount. For example, the controller may set the amount of treated water sprayed into the processing space 201 as the reference ejection amount by increasing the individual ejection amount of each of the spray nozzles 220 to the maximum value. Additionally, in another embodiment, the controller may increase the amount of treated water sprayed into the processing space 201 by increasing the number of spray nozzles 220 that spray treated water. For example, the controller may control the spray nozzles 220 so that treated water is sprayed from only one of the spray nozzles 220 in the first operating condition, may control the spray nozzles 220 so that treated water is sprayed from two of the spray nozzles 220 in the second operating condition, and may control the spray nozzles 220 so that treated water is sprayed from all spray nozzles 220 in the third operating condition.

Depending on example embodiments, the controller may adjust the amount of treated water supplied to the treated water supply pipe 207 to which the plurality of spray nozzles 220 are connected. At least one valve (e.g., treated water valve 140) may be connected to the treated water supply pipe 207, and the controller may control the amount of treated water flowing along the treated water supply pipe 207 by adjusting the opening and closing operation and the degree of opening and closing of the valve. In this manner, while maintaining the ejection amount of each of the plurality of spray nozzles 220, the amount of treated water flowing through the treated water supply pipe 207 is increased to the maximum. In the third operating condition, the amount of treated water sprayed into the processing space 201 may be set as the reference ejection amount.

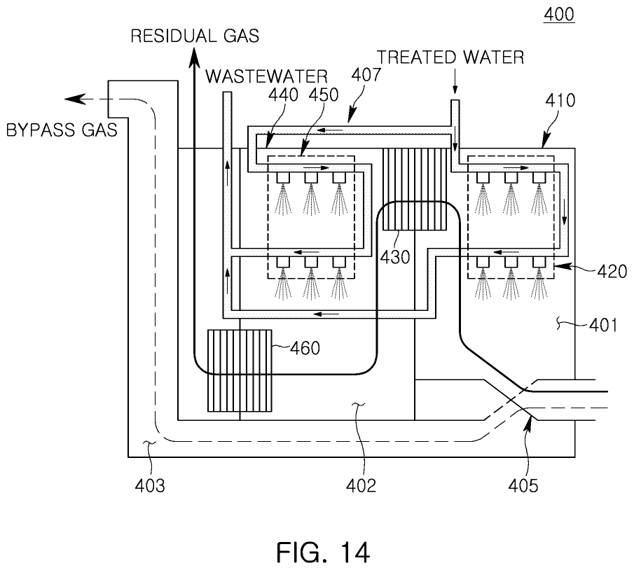

FIG. 14 is a diagram illustrating a scrubber apparatus according to example embodiments.

Referring to FIG. 14, a scrubber apparatus 400 according to example embodiments may have a multi-stage structure including a plurality of chambers 410 and 440. The first scrubber stage includes a first chamber 410 that provides a first processing space 401, and the first chamber 410 may be connected to an air intake unit including a plate 405. The air intake unit is connected to a plurality of processing chambers that discharge exhaust gas. For example, a plurality of processing chambers connected to the air intake unit may be included in one semiconductor processing apparatus. A plurality of first spray nozzles 420 connected to the treated water supply pipe 407 are installed in the first chamber 410, and the plurality of first spray nozzles 420 may spray treated water, such as deionized water, into the first processing space 401.

For example, the second scrubber stage may include a second chamber 440 connected to the first chamber 410 and the first filter 430. The second chamber 440 may provide a second processing space 402 for reducing pollutants in the exhaust gas that has passed through the first chamber 410 after flowing into the air intake unit. The second processing space 402 may be connected to a gas discharge unit through which residual gas is discharged through the second filter 460. A plurality of second spray nozzles 450 connected to the treated water supply pipe 407 are installed in the second chamber 440, and the plurality of second spray nozzles 450 may spray treated water, such as deionized water, into the second processing space 402.

When a semiconductor processing proceeds in at least one of the processing chambers included in the semiconductor processing equipment connected to the scrubber apparatus 400 and the resulting exhaust gas is emitted, the controller of the scrubber apparatus 400 may move the plate 405 to suck exhaust gas into the first processing space 401 rather than the bypass path 403. Additionally, treated water may be sprayed into the first processing space 401 using a plurality of first spray nozzles 420. Therefore, pollutants contained in the exhaust gas, such as volatile organic compounds, may be reduced by dissolving in the treated water.

The exhaust gas from which at least some of the contaminants have been removed in the first processing space 401 may pass through the first filter 430 and proceed to the second processing space 402. In this manner, at least one fan for advancing exhaust gas from the first processing space 401 to the second processing space 402 may be included in the scrubber apparatus 400.

The controller of the scrubber apparatus 400 may control the plurality of second spray nozzles 450 to spray treated water into the second processing space 402 as well. Accordingly, at least some of the remaining contaminants not removed from the first processing space 401 may be removed from the second processing space 402. Thereafter, the residual gas that has passed through the second filter 460 may be discharged to the outside of the scrubber apparatus 400.

In an example embodiment illustrated in FIG. 14, pollutants contained in exhaust gas may be removed with treated water in two stages. Therefore, compared to a scrubber apparatus including one stage, the removal efficiency of pollutants contained in exhaust gas may be improved.

The amount of treated water sprayed into each of the first processing space 401 and the second processing space 402 may vary depending on the operating status of the processing chambers that discharge exhaust gas to the scrubber apparatus 400. For example, the controller of the scrubber apparatus 400 may determine the number of active processing chambers that emit exhaust gas while performing a semiconductor processing among the processing chambers, and may control the ejection amount of treated water from the spray nozzles 420 and 450 by classifying operating conditions according to the active processing chamber. In example embodiments, the ejection amount of treated water from the spray nozzles 420 and 450 may be set as illustrated in Table 1 below.

TABLE 1

| | | | | | | | | Treated | Treated |
|---|---|---|---|---|---|---|---|---|---|
| | | | | | | | | Water | Water |
| | | MODE | MODE | MODE | INLET | OUTLET | DRE | Usage | Usage |
| | | 1 | 2 | 3 | (PPM) | (PPM) | (%) | (L/H) | (LPM) |
| First | Comparative | 100% | 100% | 100% | 534 | 78 | 85.4 | 1000 | 16.67 |
| Process | Example | | | | | | | | |
| | Example | 20% | 50% | 100% | 535 | 86 | 84.1 | 682 | 11.37 |
| | Embodiment | | | | | | | | |
| Second | Comparative | 100% | 100% | 100% | 492 | 72 | 85.4 | 1000 | 16.67 |
| Process | Example | | | | | | | | |
| | Example | 20% | 50% | 100% | 479 | 76 | 83.9 | 649 | 10.82 |
| | Embodiment | | | | | | | | |

In Table 1 above, the first mode MODE 1 corresponds to an operating condition in which no active processing chamber exists, and the second mode MODE 2 may correspond to a condition in which the number of active processing chambers exists and is the first reference number or less. Meanwhile, the third mode MODE 3 may correspond to a condition in which the number of active processing chambers is greater than the first reference number.

Each of a first process and a second process may be a semiconductor process performed in different conditions. For example, each of the first process and the second process may be a cleaning process performed based on different recipes. A case in which the first process is performed in a plurality of processing chambers included in a semiconductor processing apparatus will first be described. Referring to Table 1, in a comparative example in which the amount of treated water sprayed from the spray nozzles 420 and 450 is maintained at the maximum reference ejection amount regardless of the number of active processing chambers, 1000 liters of treated water per hour, or 16.67 liters of treated water per minute, may be consumed. In the comparative example, 85.4% of the inhaled contaminants may be removed.

In example embodiments, the operating conditions are classified according to the number of active processing chambers and the treated water ejection amount of the spray nozzles 420 and 450 is adjusted, The amount of treated water used may be reduced compared to the comparative example. Referring to Table 1, only in the third operating condition, the treated water ejection amount of the spray nozzles 420 and 450 is maintained at the maximum reference ejection amount. However, in the second operating condition, the ejection amount of treated water from the spray nozzles 420 and 450 may be set to 50% of the reference ejection amount. Additionally, in the first operating condition, the ejection amount of treated water from the spray nozzles 420 and 450 may be lowered to 20% of the reference ejection amount.

In this manner, by adjusting the ejection amount of treated water from the spray nozzles 420 and 450 according to the number of active processing chambers, the amount of treated water used may be reduced to 682 liters per hour and 11.37 liters per minute, as illustrated in Table 1. Furthermore, the removal rate of pollutants in the example embodiment in Table 1 may be maintained at a level of 84.1%, which is not significantly different from the comparative example. Therefore, the efficiency of the scrubber apparatus 400 may be improved by maintaining the removal performance of pollutants at almost the same level while using less treated water than the comparative example, by 30% or more.

Referring to Table 1 for the case where the second process is performed in a plurality of processing chambers included in the semiconductor processing apparatus, in a comparative example in which the amount of treated water sprayed from the spray nozzles 420 and 450 is maintained at the maximum reference ejection amount regardless of the number of active processing chambers, 1000 liters of treated water per hour, or 16.67 liters per minute, may be consumed. Regardless of the type of process, the ejection amount of treated water from the spray nozzles 420 and 450 is maintained at the maximum, and thus, compared to the first process, the same amount of treated water may be used in the scrubber apparatus 400.

In example embodiments, the operating conditions are classified according to the number of active processing chambers and the treated water ejection amount of the spray nozzles 420 and 450 is adjusted, and thus, the amount of treated water used may be reduced compared to the comparative example. Referring to Table 1, only in the third operating condition, the treated water ejection amount of the spray nozzles 420 and 450 is maintained at the maximum reference ejection amount, and in the second operating condition, the ejection amount of treated water from the spray nozzles 420 and 450 may be set to 50% of the reference ejection amount. In the first operating condition, the ejection amount of treated water from the spray nozzles 420 and 450 may be lowered to 20% of the reference ejection amount.

In this manner, by adjusting the ejection amount of treated water from the spray nozzles 420 and 450 according to the number of active processing chambers, as illustrated in Table 1, treated water usage may be reduced to 649 liters per hour and 10.82 liters per minute. Furthermore, the removal rate of pollutants in the example embodiment in Table 1 may be maintained at a level of 83.9%, which is not much different from the comparative example. Therefore, the efficiency of the scrubber apparatus 400 may be improved by maintaining the removal performance of pollutants at almost the same level while less using 35% or more of treated water, than in the comparative example.

As previously described with reference to FIG. 2 and the like, when a cleaning process is performed in processing chambers that discharge exhaust gas to the scrubber apparatus 400, treated water, such as deionized water, may also be supplied to a semiconductor processing apparatus. In example embodiments, the scrubber apparatus 400 may recover and use recyclable treated water that is bypassed or circulated in the processing chambers.

For example, assuming that a cleaning process is performed in processing chambers and eight processing chambers are connected to one scrubber apparatus 400, the scrubber apparatus 400 may recover 2.4 to 3.72 liters of treated water per minute from eight processing chambers. By combining the above second process with a method in which the scrubber apparatus 400 recovers and reuses treated water from the processing chambers, the amount of treated water used by the scrubber apparatus 400 per minute may be reduced by up to 7.1 liters. Therefore, the amount of treated water used by the scrubber apparatus 400 may be reduced to a level of 43% compared to the comparative example, and the efficiency of the scrubber apparatus 400 may be improved.

In Table 1, although it is described that the treated water ejection amounts of the plurality of first spray nozzles 420 and the plurality of second spray nozzles 450 are controlled equally according to the operation modes MODE 1, MODE 2 and MODE 3, aspects of the present inventive concept are not necessarily limited to this form. For example, the controller of the scrubber apparatus 400 may control the amount of treated water sprayed by the plurality of first spray nozzles 420 into the first processing space 401, to be different from the amount of treated water sprayed by the plurality of second spray nozzles 450 into the second processing space 402.

As set forth above, according to example embodiments, the number of active processing chambers actually performing semiconductor processing among a plurality of processing chambers that are connected to a scrubber apparatus and discharging exhaust gas may be determined, and the amount of treated water used by the scrubber apparatus may be dynamically controlled based on the number of active processing chambers. By adjusting the amount of treated water used based on the amount of exhaust gas discharged from the semiconductor process, the amount of treated water used may be reduced without reducing a treatment efficiency of pollutants.

While example embodiments have been illustrated and described above, it will be apparent to those skilled in the art that modifications and variations could be made without departing from the scope of the present inventive concept as defined by the appended claims.

What is claimed is:

1. A scrubber apparatus comprising:
a chamber;
an air intake unit connected to a semiconductor processing apparatus including a plurality of processing chambers and intaking exhaust gas discharged from the plurality of processing chambers into a processing space inside the chamber;
a treated water supply pipe installed in the processing space, connected to a plurality of spray nozzles spraying treated water, and configured to supply the treated water to the processing space;
a wastewater discharge unit configured to discharge wastewater in which the exhaust gas is dissolved by the treated water, from the processing space;
a gas discharge unit connected to the chamber and configured to discharge residual gas; and
a controller communicatively connected to the semiconductor processing apparatus and configured to adjust an amount of the treated water supplied to the processing space based on the number of active processing chambers in progress among the plurality of processing chambers.

2. The scrubber apparatus of claim 1, further comprising:
a filter disposed in front of the gas discharge unit and filtering the residual gas.

3. The scrubber apparatus of claim 1, wherein the air intake unit is connected to the plurality of semiconductor processing apparatuses performing a cleaning process using an organic solvent.

4. The scrubber apparatus of claim 1, wherein the air intake unit includes a bypass configured to intake the exhaust gas into the processing space or bypass the exhaust gas.

5. The scrubber apparatus of claim 1, wherein the controller controls the amount of the treated water sprayed from each of the plurality of spray nozzles based on the number of the active processing chambers.

6. The scrubber apparatus of claim 5, wherein, when the number of the active processing chambers is greater than a first reference number, the controller sets the amount of the treated water sprayed from each of the plurality of spray nozzles as a reference ejection amount, and
when the number of the active processing chambers is less than or equal to the first reference number, the controller sets the amount of the treated water sprayed from each of the plurality of spray nozzles to 50% of the reference ejection amount.

7. The scrubber apparatus of claim 6, wherein, when the number of the active processing chambers is equal to or less than the first reference number, and more than a second reference number, the controller sets the amount of the treated water sprayed from each of the plurality of spray nozzles to 50% of the reference ejection amount, and
when the number of the active processing chambers is less than or equal to the second reference number, the controller sets the amount of the treated water sprayed from each of the plurality of spray nozzles to 20% of the reference ejection amount.

8. The scrubber apparatus of claim 1, wherein the controller adjusts the number of spray nozzles spraying the treated water among the plurality of spray nozzles based on the number of the active processing chambers.

9. The scrubber apparatus of claim 8, wherein the controller sets each of the plurality of spray nozzles to spray the treated water when the number of the active processing chambers is equal to the number of the plurality of semiconductor processing apparatuses, and
the controller sets the number of spray nozzles spraying the treated water to half among the plurality of spray nozzles when the number of the active processing chambers is less than or equal to a first reference number.

10. The scrubber apparatus of claim 1, wherein the controller is communicatively connected to the plurality of semiconductor processing apparatuses through a TCP/IP interface.

11. The scrubber apparatus of claim 1, wherein the treated water is de-ionized water.

12. The scrubber apparatus of claim 1, wherein the treated water supply pipe receives the treated water discharged from at least one of the plurality of processing chambers.

13. A scrubber apparatus comprising:
a first scrubber stage including an air intake unit intaking exhaust gas discharged from a plurality of processing chambers, a plurality of first spray nozzles spraying treated water into the exhaust gas drawn by the air intake unit, and a first chamber connected to the air intake unit and providing a first processing space in which the exhaust gas is dissolved in the treated water sprayed from the plurality of first spray nozzles;
a second scrubber stage including a plurality of second spray nozzles spraying the treated water onto the exhaust gas having passed through the first scrubber stage, a second chamber separated from the first processing space and providing a second processing space in which the exhaust gas is dissolved in the treated water sprayed from the plurality of second spray nozzles, and a gas discharge unit discharging residual gas having passed through the second processing space; and
a controller configured to adjust an amount of the treated water supplied to each of the first processing space and the second processing space based on the number of active processing chambers in progress among the plurality of processing chambers.

14. The scrubber apparatus of claim 13, further comprising:
a first filter disposed between the first processing space and the second processing space and filtering the exhaust gas transferred from the first scrubber stage to the second scrubber stage; and
a second filter between the second processing space and the gas discharge unit.

15. The scrubber apparatus of claim 13, further comprising:
a wastewater discharge unit configured to discharge wastewater generated by dissolving the exhaust gas in the treated water from each of the first processing space and the second processing space.

16. The scrubber apparatus of claim 13, wherein the controller sets an amount of the treated water sprayed by the plurality of first spray nozzles into the first processing space, to be equal to an amount of the treated water sprayed by the plurality of second spray nozzles into the second processing space.

17. The scrubber apparatus of claim 13, wherein the controller sets the amount of the treated water sprayed by the plurality of first spray nozzles into the first processing space, to be different from an amount of the treated water sprayed by the plurality of second spray nozzles into the second processing space.

18. The scrubber apparatus of claim 13, wherein, when the number of the active processing chambers is equal to the number of the plurality of processing chambers, the controller sets an amount of the treated water sprayed from each of the plurality of first spray nozzles and the plurality of second spray nozzles, as a reference ejection amount, and
when the number of the active processing chambers is less than or equal to a first reference number, the controller sets the amount of the treated water sprayed from each of the plurality of first spray nozzles and the plurality of second spray nozzles, to 50% of the reference ejection amount.

19. The scrubber apparatus of claim 18, wherein, when the number of the active processing chambers is less than or equal to the first reference number and greater than a second reference number, the controller controls the amount of the treated water sprayed from each of the plurality of first spray nozzles and the plurality of second spray nozzles, to 50% of the reference ejection amount, and
when the number of the active processing chambers is less than or equal to the second reference number, the controller sets the amount of the treated water sprayed from each of the plurality of first spray nozzles and the plurality of second spray nozzles, to 20% of the reference ejection amount.

20. A scrubber apparatus comprising:
a chamber;
an air intake unit connected to a plurality of processing chambers and intaking exhaust gas discharged from the plurality of processing chambers into a processing space inside the chamber;
a treated water supply pipe installed in the processing space, connected to a plurality of spray nozzles spraying treated water, and supplying the treated water to the processing space;
a wastewater discharge unit configured to discharge wastewater in which the exhaust gas is dissolved by the treated water from the processing space; and
a gas discharge unit connected to the chamber and discharging residual gas,
wherein the treated water supply pipe receives the treated water discharged after circulation in at least one of the plurality of processing chambers.
